(19) United States
(12) Patent Application Publication
(10) Pub. No.: US 2026/0136872 A1
(43) Pub. Date: May 14, 2026

(54) LIQUID CHEMICAL SUPPLY SYSTEM HAVING LEAK DETECTION AND RELATED METHODS

(71) Applicant: Taiwan Semiconductor Manufacturing Company Limited, Hsin-Chu (TW)

(72) Inventors: Feng-An YANG, Hsinchu City (TW); Hsu TIEN-TZE, Hsinchu City (TW); Heng-Yi TSENG, Hsinchu County (TW); Ching-Jung HSU, Hsinchu City (TW); Shun Chan TENG, Hsinchu County (TW); Yi-Lung CHUNG, Hsin-Chu (TW)

(21) Appl. No.: 18/940,948

(22) Filed: Nov. 8, 2024

(51) Int. Cl. H01L 21/67; G01M 3/28; G01M 3/32

(52) U.S. Cl. CPC H10P 72/0441; G01M 3/2846; G01M 3/3272; H10P 72/0402; H10P 72/0448

(57) ABSTRACT

A method is provided. The method includes: receiving a storage tank that holds a liquid chemical therein; attaching an inlet nozzle to the storage tank, the inlet nozzle including: a first opening defined therein, the first opening in fluid communication with an interior of the storage tank; a second opening defined therein, the second opening in gas communication with the interior of the storage tank; a third opening defined therein; and a first O-ring in contact with the third opening; and performing a semiconductor process via the liquid chemical.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a system for supplying a material, in accordance with some embodiments.

FIG. 2A illustrates a diagrammatic side view of an inlet nozzle, in accordance with some embodiments.

FIG. 2B illustrates a diagrammatic plan view of the inlet nozzle, in accordance with some embodiments.

FIG. 2C illustrates a detailed diagrammatic view of a region of the inlet nozzle during a leaking condition, in accordance with some embodiments.

FIG. 2D illustrates a detailed diagrammatic view of a region of the inlet nozzle during a sealed condition, in accordance with some embodiments.

FIG. 3A illustrates a diagrammatic side view of an outlet nozzle, in accordance with some embodiments.

FIG. 3B illustrates a diagrammatic plan view of the outlet nozzle, in accordance with some embodiments.

FIG. 3C illustrates a detailed diagrammatic view of a region of the outlet nozzle during a leaking condition, in accordance with some embodiments.

FIG. 3D illustrates a detailed diagrammatic view of a region of the outlet nozzle during a sealed condition, in accordance with some embodiments.

FIG. 4 illustrates a perspective view of an identification system of the system, in accordance with some embodiments.

FIG. 5 illustrates a schematic view of a tank monitoring system, in accordance with some embodiments.

FIG. 6 is a flow diagram illustrating a method of operating a liquid chemical supply system, in accordance with some embodiments.

FIG. 7 is a flow diagram illustrating a method, in accordance with some embodiments.

FIG. 8 is a flow diagram illustrating a method, in accordance with some embodiments.

FIG. 9 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, process quality and yield are increasingly sensitive to external air contamination in liquid chemical supplies. When a seal between an outlet nozzle and a storage tank holding the liquid chemical is not complete when starting a pump, external air is pumped into a system pipeline and causes contamination of the liquid chemical supplied to a processing tool. When a seal between an inlet nozzle of a feedback line to the storage tank is not complete when starting the pump, leakage and/or splashing of the liquid chemical outside the storage tank can occur, causing an industrial safety incident.

In embodiments of the disclosure, inlet and outlet nozzles are included that can be used to detect whether the connection or seal is complete. A pressure-maintaining channel and an O-ring are pressed together to form an airtight path. Prior to supply of liquid chemical, a slight positive gas pressure is applied using an inert gas and pressure thereof is monitored by a controller, which can reduce uncertainty that the inlet and/or outlet nozzle has been properly installed, avoiding leakage and external air contamination.

Embodiments of the system also include radio frequency identification (RFID) to identify materials independently to reduce occurrence of mistaken liquid chemical being supplied via the system. An RFID reader may be used to scan a storage tank barcode to actively identify material number and/or batch number associated with the liquid chemical, and to combine with an automatic feeding system to prevent wrong liquid chemical(s) from entering and/or exiting the system.

A quality analyzer is included in the system, in some embodiments. Prior to a pumping cycle, a small amount of liquid chemical is extracted and delivered to the quality analyzer to confirm a parameter(s) of the liquid chemical and whether the storage tank includes a wrong liquid chemical, which improves prevention of supplying the wrong liquid chemical due to human error.

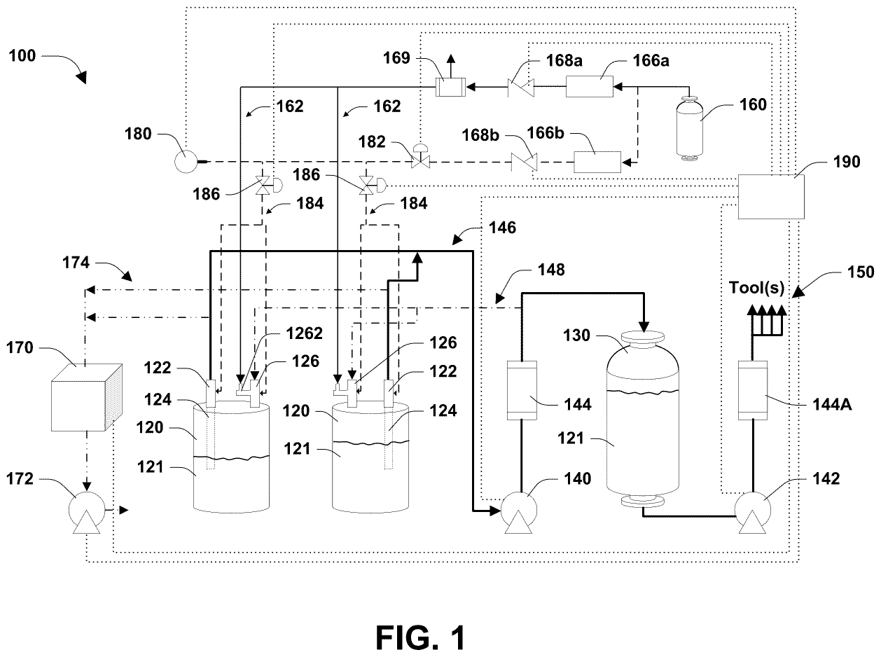

FIG. 1 illustrates a schematic view of a system 100 for supplying a material, such as a liquid chemical 121, in accordance with some embodiments.

In some embodiments, liquid chemicals 121 are transferred from storage tank(s) 120 to a supply tank 130, then from the supply tank 130 to one or more semiconductor processing tools 150. Pumps 140, 142 drive the liquid transfer, with flow controlled optionally by valves and monitored by sensors to improve safe operation. Levels of liquid chemical 121 in the system 100, such as in the storage tank(s) 120 and the supply tank 130 can be monitored to prevent overfilling, and leak detection systems are optionally included.

The system 100 can include one or more storage tanks 120, pumps 140, 142, 172, filtration systems 144, 144A, monitoring systems 180, quality measurement systems or “measurement apparatus” 170, and the like. Liquid chemical 121 can be supplied from the supply tank 130 to online tools 150, such as etchers or cleaners, through a system of pipelines and pumps 140, 142 selected to provide uniform flow and pressure.

The pumps 140, 142 draw the liquid chemical 121 from the storage tank(s) 120 and transport it through compatible pipelines, with optional valves and flow meters controlling and monitoring the flow. The pumps 140, 142 can be calibrated for the selected liquid chemical 121. A pipeline or “transport line” 146 is labeled in FIG. 1. The liquid chemical 121 may pass through a filtration system(s) 144, 144A to remove particulates prior to being supplied to the tools 150, where the liquid chemical 121 is introduced into process chambers of the tools 150. In some embodiments, excess liquid chemical 121 is collected for reuse or waste treatment, providing safe and precise delivery of the liquid chemical 121 to support the manufacturing process.

In some embodiments, the tools 150 are operable to perform one or more semiconductor manufacturing process operations on a semiconductor wafer. The semiconductor wafer comprises at least one of a substrate, a photomask, a semiconductor device, a dielectric layer, an epitaxial layer, a silicon-on-insulator (SOI) structure, a semiconductor layer, a conductive material layer, a die, etc. The semiconductor wafer comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor wafer comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor wafer are within the scope of the present disclosure.

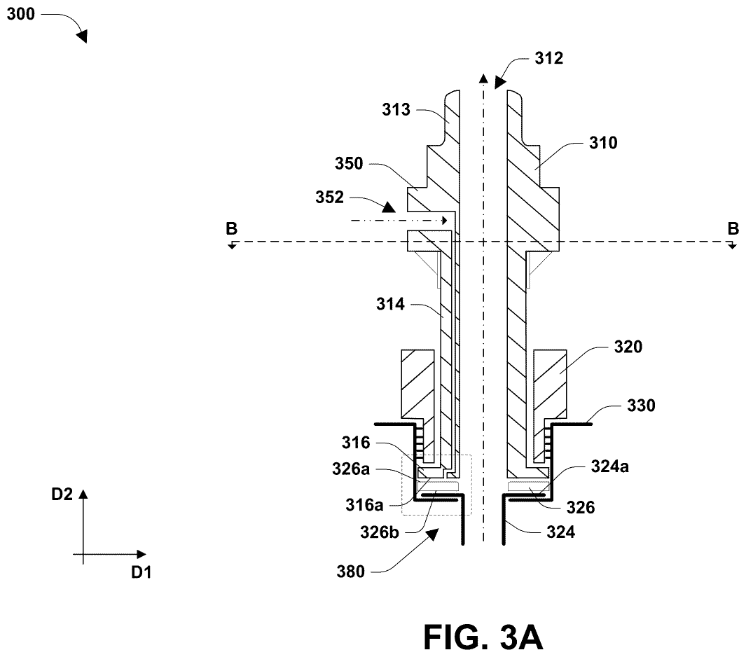

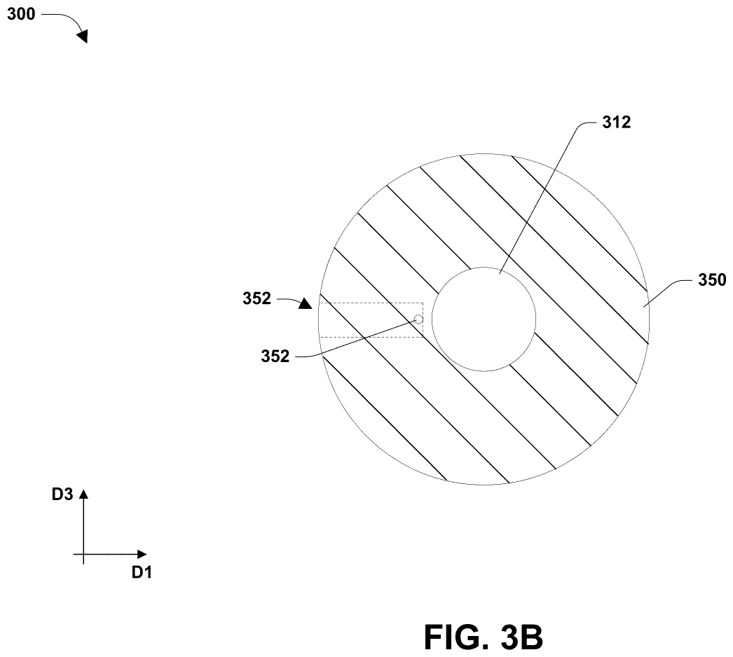

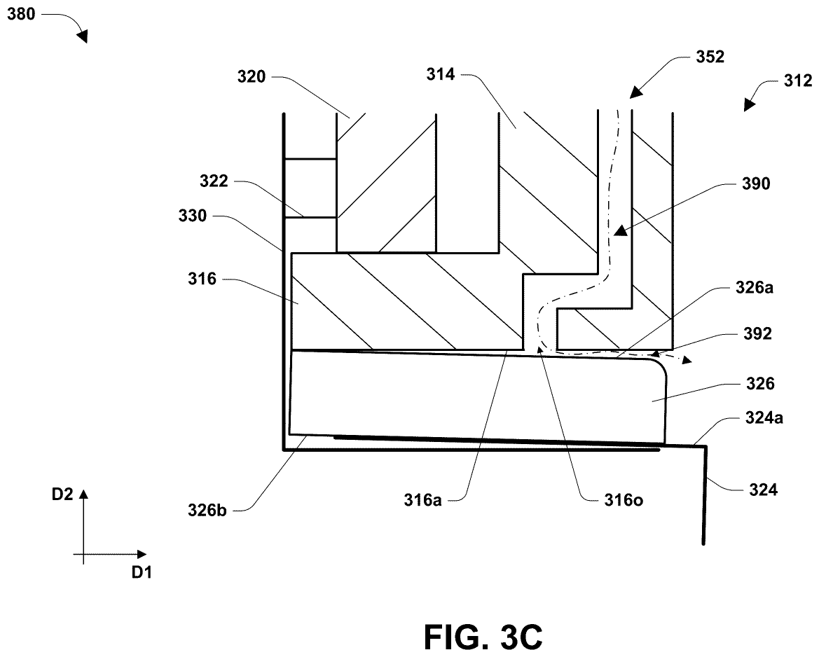

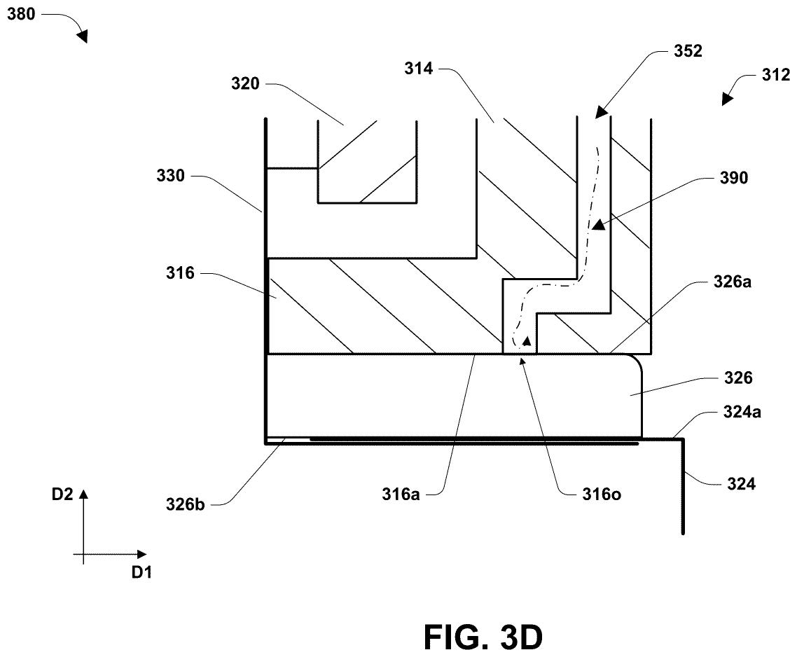

The storage tank(s) 120 has an outlet or output nozzle 122 and an inlet or input nozzle 126 mounted or attached thereto. The outlet nozzle 122 is operable to draw the liquid chemical 121 out of an interior of the storage tank 120 via a tube 124 that extends into the interior of the storage tank 120. The liquid chemical 121 passes through the outlet nozzle 122 to the transport line 146. Drawing of the liquid chemical 121 out of the storage tank 120 via the tube 124 and the outlet nozzle 122 can be via pumping by the pump 140, which is in fluid communication with the storage tank 120 via the transport line 146. An outlet nozzle 300 that is an embodiment of the outlet nozzle 122 is described in greater detail with reference to FIGS. 3A-3D.

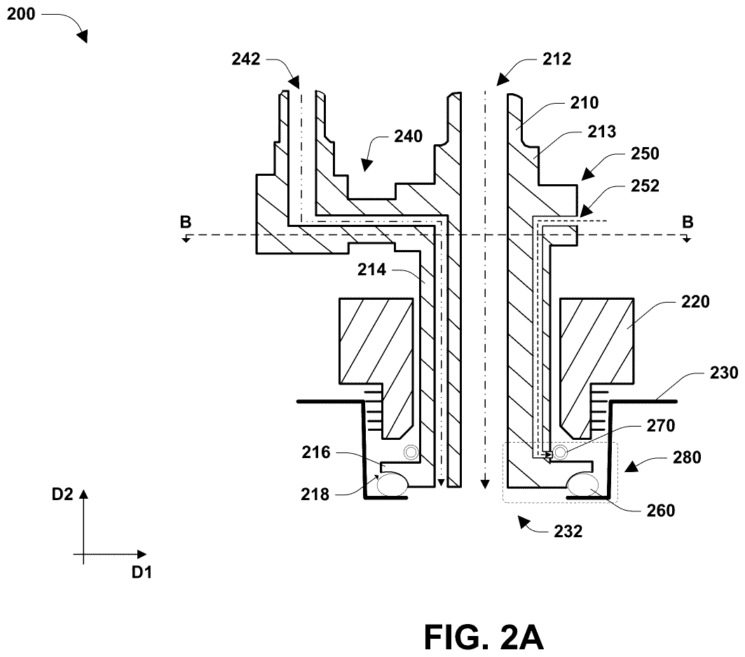

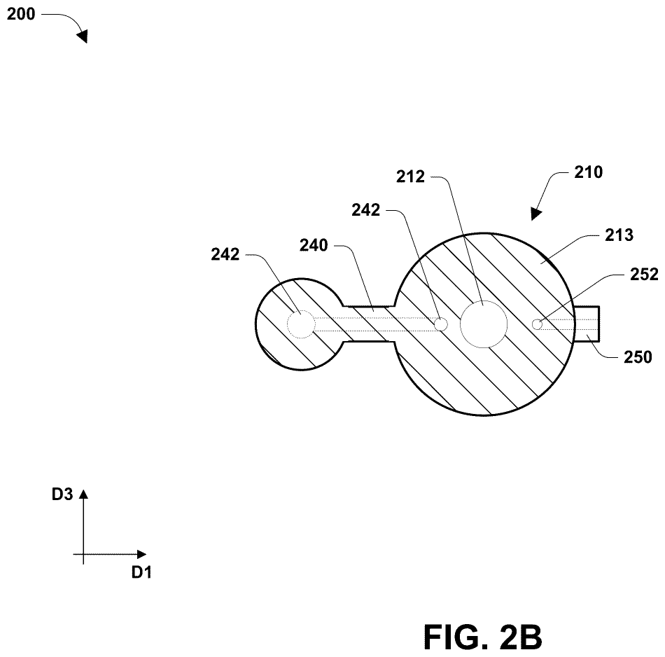

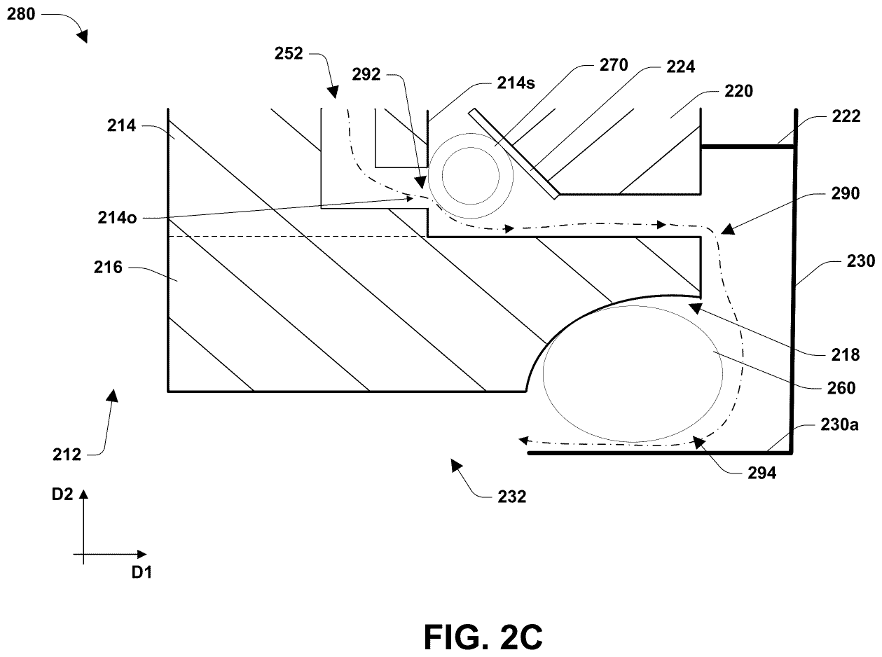

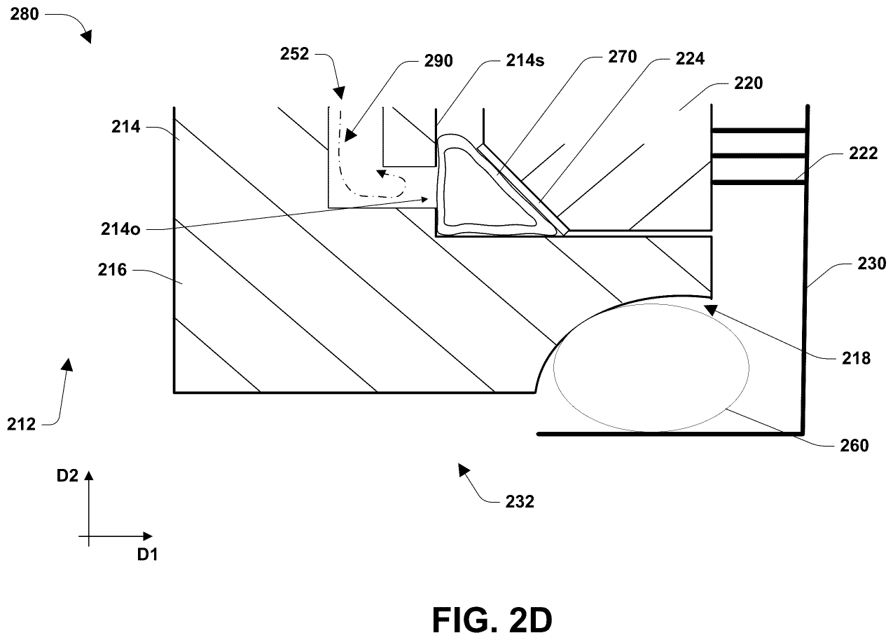

The inlet nozzle 126 is operable to at least (i) receive liquid chemical 121 fed back to the storage tank 120 via a transport line 148, and (ii) transport pressure stabilizing gas from a gas supply 160 to the storage tank 120 via a gas transport line 162 and a gas inlet structure 1262 thereof. An inlet nozzle 200 that is an embodiment of the inlet nozzle 126 is described in greater detail with reference to FIGS. 2A-2D.

The system 100 includes a gas supply 160, which can be or include a gas storage tank 160. The gas supply 160 can store and supply one or more inert gases, such as N₂, He, Ar, CO₂, or the like. In some embodiments, the gas supply 160 is in gas communication via gas transport lines with one or more flow meters (FFMs) 166a, 166b, which are flow-rate flow meters, fixed flow meters, filtered flow meters, or the like. The FFMs 166a, 166b are each in gas communication via gas transport lines with one or more valves 168a, 168b, which may be check valves, such as pressure control check valves, in accordance with some embodiments.

Gas transport lines 162 are in gas communication with the valve 168a, and gas transport lines 184 are in gas communication with the valve 168b. The gas transport lines 162 are in gas communication with the gas inlet structure 1262 of the inlet nozzle(s) 126. The gas transport lines 184 are in gas communication with leak detection openings of the outlet and inlet nozzles 122, 126. The leak detection openings are described in greater detail with reference to FIGS. 2A-3D.

An exhaust port 169 is positioned between and in gas communication with the valve 168a and the gas transport line(s) 162. In operation, the exhaust port 169 can exhaust excess gas that is present in the gas supply 160, the flow meter 166, and/or the gas transport line(s) 162.

First and second valves 182, 186 are present between and in gas communication with the valve 168b and the gas transport lines 184. The first valve 182 and the second valves 186 are pneumatic valves, in some embodiments, and may be other suitable valves in some embodiments. The first valve 182, in operation, controls flow of the gas from the valve 168b to the second valves 186. The second valves 186, in operation, control flow of the gas from the first valve 182 to the outlet and inlet nozzles 122, 126.

The monitoring system 180, which may be a pressure meter 180, is in gas communication with the first valve 182 and the gas transport lines 184, which are in gas communication with the leak detection openings of the outlet and inlet nozzles 122, 126. The pressure meter 180 or “pressure gauge,” is a device that, in operation, measures the pressure of the gas within the system 100. In some embodiments, the pressure meter 180 is or includes a Bourdon tube, which is a curved, flexible, hollow metal tube that straightens as the gas pressure increases. The Bourdon tube can be made from brass, bronze, or stainless steel. Movement of the Bourdon tube is transferred to a mechanical linkage system. As the tube straightens or curls with changes in pressure, this movement is transmitted to a gear mechanism. The gear mechanism drives a pointer across a calibrated dial that displays the pressure reading. The dial is marked in units of pressure (such as psi, bar, or Pa). The dial is typically circular and may include multiple scales to show pressure in different units. In some embodiments, the pressure meter 180 is a digital pressure gauge, which can be or include a piezoelectric, strain gauge or capacitive sensor that may be paired with a transducer. The digital pressure gauge can convert mechanical pressure into an electronic signal that can be processed by a microprocessor and output as pressure data.

In operation, the pressure meter 180 can obtain pressure readings and output the pressure readings as pressure data. The pressure data can indicate a pressure level of the gas in the leak detection openings of the outlet and inlet nozzles 122, 126. Based on the pressure data, a determination can be made whether the pressure level exceeds a selected threshold value. In response to the pressure level exceeding the selected threshold value, the system 100 can enter a normal operation mode or state based on no leakage being detected between the outlet and/or inlet nozzles 122, 126 and the storage tank(s) 120. In response to the pressure level not exceeding the selected threshold value, the system 100 can enter a warning, hold or conditional operation mode or state based on leakage being detected between the outlet and/or inlet nozzle 122, 126 and the storage tank(s) 120. Namely, when the outlet and/or inlet nozzle 122, 126 is properly sealed with the storage tank 120, the gas entering the leak detection opening has nowhere to escape to, and the pressure measured by the pressure meter 180 increases. When the outlet and/or inlet nozzle 122, 126 is not properly sealed with the storage tank 120, the gas entering the leak detection opening leaks through one or more leakage paths, and the pressure measured by the pressure meter 180 is unable to increase to the selected threshold value. In the warning, hold or conditional operation mode or state, a notification may be generated and outputted to inform a human operator or automated system that one or both of the outlet and/or inlet nozzle 122, 126 is not properly installed. Then, the operator or automated system may reinstall the outlet and/or inlet nozzle 122, 126.

The system 100 includes a measurement apparatus 170 that is in fluid communication with the storage tanks 120 via the transport lines 146 and measurement transport lines 174. The measurement apparatus 170 is in fluid communication with the pump 172. In operation, a small quantity or sample of the liquid chemical 121 can be drawn through the measurement apparatus 170 by the pump 172. The measurement apparatus 170 can determine one or more characteristics of the liquid chemical 121 by performing one or more measurements on the sample of the liquid chemical 121 drawn therethrough. In some embodiments, the measurement apparatus 170 can measure or perform one or more of (i) pH, (ii) conductivity, (iii) refractive index, (iv) density, (v) specific gravity, (vi) ultraviolet spectroscopy, (vii) turbidity, (viii) temperature, (ix) total organic carbon, (x) redox potential, (xi) viscosity, (xii) infrared spectroscopy, (xiii) ion chromatography, (xiv) particulate counting, other measurements, or the like. Based on the one or more measured characteristics, the measurement apparatus 170 or an external processor (e.g. a controller 190) can determine whether the liquid chemical 121 in the storage tank(s) 120 is a selected liquid chemical for supply to the tools 150. In response to the liquid chemical 121 being the selected liquid chemical based on the measurement(s), the system 100 can enter or remain in a normal operation mode or state. In response to the liquid chemical 121 not being the selected liquid chemical based on the measurement(s), the system 100 can enter or remain in a warning, hold or conditional operation mode or state. In the warning, hold or conditional operation mode or state, a notification may be generated and outputted to inform a human operator or automated system that the storage tanks 120 do not contain the selected liquid chemical. Then, the operator or automated system may disconnect the storage tank(s) 120, remove the storage tank(s) 120, and replace the storage tank(s) 120 with other storage tank(s) that contain the selected liquid chemical. Additional actions may be taken, such as draining or flushing the supply tank 130 and the transport lines that are in fluid communication with the storage tank(s) 120 and the supply tank 130.

One or more elements of the system 100 may be omitted from view for simplicity of illustration. For example, additional valves may be present on the transport lines 146, 148, 174 to control flow of the liquid chemical 121 to various elements of the system 100, such as the measurement apparatus 170. In another example, a valve manifold box (VMB) may be present following the filtration system 144A and the tools 150 to select which tool(s) 150 to direct flow of the liquid chemical 121 to.

[symbol]

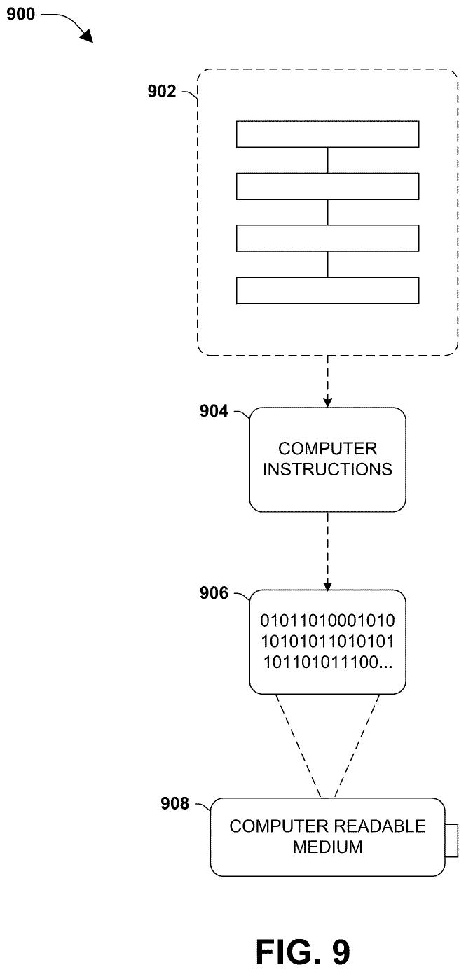

In FIG. 1, a controller 190 is included in the system 100 that can be in data communication with one or more elements of the system 100 to (i) control operation thereof, (ii) read data therefrom, or both. As depicted, in some embodiments, the controller 190 is in data communication with the pumps 140, 142, 172, the valves 168a, 168b, 182, 186, and the pressure meter 180. The controller 190 may optionally be in data communication with the flow meters 166a, 166b and additional valves not depicted in FIG. 1. An embodiment of the controller 190 is described with reference to FIG. 9. In some embodiments, the controller 190 can be or include a microcontroller (MCU), microprocessor (MPU), programmable logic controller (PLC) or the like.

The controller 190 can, for example, read pressure data from the pressure meter 180, compare the pressure data with the selected pressure threshold value, and determine whether a leak is present based on the comparison. In another example, the controller 190 can read measurement data from the measurement apparatus 170, compare the measurement data with characteristic data associated with the selected liquid chemical, and determine whether the liquid chemical 121 is the selected liquid chemical based on the measurement data.

FIG. 2A illustrates a diagrammatic side view of an inlet nozzle 200, in accordance with some embodiments. FIG. 2B illustrates a diagrammatic plan view of the inlet nozzle 200 along sectional line B-B of FIG. 2A. The inlet nozzle 200 is an embodiment of the inlet nozzle 126 described with reference to FIG. 1.

In FIG. 2A, the inlet nozzle 200 is attached to an inlet 230 of a storage tank, which can be the storage tank 120 of FIG. 1. A first O-ring 260 is positioned between the inlet nozzle 200 and the inlet 230 to establish a seal therebetween. A locking assembly or structure 220 is adjacent a body 210 of the inlet nozzle 200 and is operable to press the body 210 against the first O-ring 260 to establish the seal.

The inlet nozzle 200 includes a body 210, which can be or include a polymer or a metal, such as polyvinyl chloride (PVC), polypropylene (PP), polytetrafluoroethylene (PTFE), perfluoroalkoxy (PFA), stainless steel, or the like.

The body 210 has an upper portion 213, a middle portion 214, and a base portion 216. A first opening 212 is defined in the body 210 and extends through the upper, middle, and base portions 213, 214, 216 of the body 210 along a second axis D2. The first opening 212 is operable to direct flow of the liquid chemical 121 fed back into the storage tank (e.g., the storage tank 120), for example, via an opening 232 in the inlet 230. The base portion 216 has a cutout region 218 that is operable to make contact with the first O-ring 260 to form a seal between the inlet nozzle 200 and the storage tank (e.g., the storage tank 120).

The body 210 has a gas inlet structure 240, which is an embodiment of the gas inlet structure 1262 described with reference to FIG. 1. The gas inlet structure 240 extends outward from the upper portion 213 of the body 210 along a first direction D1, and can have an L-shaped profile, as shown. The gas inlet structure 240, the middle portion 214, and the base portion 216 of the body 210 have a second opening 242 defined therein and extending therethrough. The second opening 242 is operable to direct gas from a gas supply (e.g., the gas supply 160) into the storage tank (e.g., the storage tank 120).

The body 210 has an extension portion 250 that extends outward from the upper portion 213 along the first axis D1. The body includes a third opening 252 extending therethrough. The third opening 252 is defined in the extension portion 250 and the middle portion 214. In some embodiments, the third opening 252 has diameter in a range of about 1 millimeter (mm) to about 5 mm, such as about 2 mm. A second O-ring 270 laterally surrounds the middle portion 214 and is at a same level as an outlet opening of the third opening 252 that is defined in a sidewall of the middle portion 214. The second O-ring 270 is positioned adjacent to the outlet opening. In operation, the locking assembly 220 presses against the second O-ring 270 in a locked position, which forms a seal between the locking assembly 220 and the body 210. The third opening 252 is operable to flow the gas from the gas supply (e.g., the gas supply 160) to a space adjacent the first O-ring 260 to determine whether a leak is present due to improper installation of the inlet nozzle 200.

A region 280 of the inlet nozzle 200 is described in greater detail with reference to FIGS. 2C and 2D.

In the top view of FIG. 2B, the first, second and third openings 212, 242, 252 are depicted. Generally, the first opening 212 has diameter that exceeds those of the second and third openings 242, 252. In some embodiments, the second opening 242 has diameter that is the same as that of the third opening 252. In some embodiments, the third opening 252 has diameter that is smaller than that of the second opening 242, which has diameter that is smaller than that of the first opening 212.

In some embodiments, the body 210 other than the gas inlet structure 240 and the extension portion 250 is substantially circular in the plane depicted by the first direction D1 and a third direction D3, both of which are transverse (e.g., perpendicular to) the second direction D2. The extension portion 250 may be a substantially rectangular extension, as depicted.

FIG. 2C illustrates a detailed diagrammatic view of a region 280 of the inlet nozzle 200 during a leaking condition, in accordance with some embodiments.

In FIG. 2C, when the inlet nozzle 200 is not properly installed, a full seal between the inlet nozzle 200 and the storage tank is not established. As such, one or more leakage paths 292, 294 is established by which the liquid chemical (e.g., the liquid chemical 121) may splash out of the storage tank, contamination from outside air may enter the storage tank, or both.

As described with reference to FIG. 2A, the middle portion 214 includes a sidewall 214s, which has an opening 214o of the third opening 252 defined therein. The second O-ring 270 is adjacent the opening 214o. A chamfered side 224 of the locking structure 220 is adjacent the second O-ring 270 and is operable to press the second O-ring 270 against the opening 214o. The locking structure 220 can have threads 222 that, in operation, interlock the locking structure 220 with the inlet 230 and tighten or loosen the locking structure 220 against the second O-ring 270.

In the leaking condition or “leak state,” the first leakage path 292, the second leakage path 294, or both may be present. The first leakage path 292 includes a gap between the second O-ring 270 and the opening 214o. Namely, the second O-ring 270 may not press against and completely cover the opening 214o. The second leakage path 294 includes a gap between the first O-ring 260 and the inlet 230 of the storage tank. Namely, the first O-ring 260 may not press against an upper surface 230a of the inlet 230. In another example, the first O-ring 260 may rest on the upper surface 230a of the inlet 230, but may not be engaged with or pressed up against the cutout region 218 of the inlet nozzle 200. As such, the second leakage path 294 may pass beneath or over the first O-ring 260, and may be between the first O-ring 260 and one of the upper surface 230a and the cutout region 218.

In some embodiments, when the opening 214o is fully sealed by the second O-ring 270, it can be assumed that the first O-ring 260 seals the space between the cutout region 218 and the upper surface 230a.

In the leaking condition, when a gas 290 flows into the third opening 252 from the gas supply, the gas flows through the first leakage path 292, the second leakage path 294, or both. As such, a pressure meter (e.g., the pressure meter 180) in gas communication with the third opening 252 does not register a pressure of the gas that exceeds a selected pressure threshold value. In response to the pressure of the gas not exceeding the selected pressure threshold value, a controller (e.g., the controller 190) can determine that the inlet nozzle 200 is not properly installed, and can halt operation of a supply system (e.g., the system 100) that supplies liquid chemical in the storage drum to semiconductor processing tools. Then, the inlet nozzle 200 can be reinstalled or reattached to achieve proper sealing thereof to the storage tank prior to entering a normal operating mode or state in which the liquid chemical is supplied to the semiconductor processing tools.

Although a situation can exist in which the second O-ring 270 is sealed while the first O-ring 260 is not sealed, generally, when the second O-ring 270 is sealed, this indicates that the inlet nozzle 200 is properly installed, such that the first O-ring 260 also achieves a sealed state due to the structure thereof. In situations in which the first O-ring 260 is sealed but the second O-ring 270 is not sealed, it can be determined that the second O-ring 270 is worn out, or a contact surface structure that contacts the second O-ring 270 on the inlet nozzle 200 is degraded.

FIG. 2D illustrates a detailed diagrammatic view of a region of the inlet nozzle 200 during a sealed condition, in accordance with some embodiments.

In the sealed condition, the locking structure 220 is pressed against the second O-ring 270, which forms a full seal of the second O-ring 270 against the opening 214o.

In the sealed condition, when the gas 290 flows into the third opening 252 from the gas supply, the gas is stopped by the seal formed by the contact of the second O-ring 270 against the opening 214o. As such, the pressure meter (e.g., the pressure meter 180) in gas communication with the third opening 252 registers a pressure of the gas that exceeds the selected pressure threshold value. In response to the pressure of the gas exceeding the selected pressure threshold value, a controller (e.g., the controller 190) can determine that the inlet nozzle 200 is properly installed, and can engage normal operation of a supply system (e.g., the system 100) to supply the liquid chemical in the storage drum to the semiconductor processing tools.

FIG. 3A illustrates a diagrammatic view of an outlet nozzle 300, in accordance with some embodiments. FIG. 3B illustrates a diagrammatic plan view of the outlet nozzle 300 along a sectional line B-B of FIG. 3A. The outlet nozzle 300 is an embodiment of the outlet nozzle 122 described with reference to FIG. 1.

The outlet nozzle 300 is operable to be installed or attached to an outlet 330 of a storage tank (e.g., the storage tank 120) via a locking structure 320. A tube 324 extends from the outlet 330 into an interior of the storage tank to draw liquid chemical (e.g., the liquid chemical 121) from the interior of the storage tank. The tube 324 has an O-ring 326 thereon for forming a seal with the outlet nozzle 300. The outlet nozzle 300, when installed, presses against the O-ring 326 to form the seal between the outlet nozzle 300, the tube 324, and the outlet 330. Presence of the seal prevents introduction of external air and contaminants thereof as bubbles in the liquid chemical that is delivered to a semiconductor processing tool (e.g., the semiconductor processing tool 150) via the outlet nozzle 300.

In FIG. 3A, the outlet nozzle 300 includes a body 310. The body 310 includes an upper portion 313, a middle portion 314, a base portion 316, and an extension portion 350.

A first opening 312 is defined in the body 310 and extends through the upper, middle, and base portions 313, 314, 316 of the body 310 along a second axis D2. The first opening 312 is operable to direct flow of the liquid chemical to a supply tank (e.g., the supply tank 130). The base portion 316 is operable to make contact with the O-ring 326 to form a seal between the outlet nozzle 300 and the tube 324.

The body 310 has an extension portion 350 that extends outward from the upper portion 313 along the first axis D1. The body 310 includes a second opening 352 extending therethrough. In some embodiments, the second opening 352 has diameter in a range of about 1 millimeter (mm) to about 5 mm, such as about 2 mm. The second opening 352 is defined in the extension portion 350, the middle portion 314, and the base portion 316. An outlet opening of the second opening 352 is defined in a lower surface of the base portion 316. The O-ring 326 is positioned adjacent to the outlet opening. In operation, the locking structure 320 presses against the base portion 316, which presses against the O-ring 326 in a locked position, which forms a seal between the body 310 and the tube 324. The second opening 352 is operable to flow the gas from the gas supply (e.g., the gas supply 160) to the O-ring 326 to determine whether a leak is present due to improper installation of the outlet nozzle 300.

A region 380 of the outlet nozzle 300 is described in greater detail with reference to FIGS. 3C and 3D.

In the top view of FIG. 3B, the first and second openings 312, 352 are depicted. Generally, the first opening 312 has diameter that exceeds that of the second opening 352.

In some embodiments, the body 310 is substantially circular in the plane depicted by the first direction D1 and a third direction D3, both of which are transverse (e.g., perpendicular to) the second direction D2. The extension portion 350 may be a substantially rectangular extension, in some embodiments, instead of the circular extension depicted in FIG. 3B.

FIG. 3C illustrates a detailed diagrammatic view of a region 380 of the outlet nozzle 300 during a leaking condition, in accordance with some embodiments.

In FIG. 3C, when the outlet nozzle 300 is not properly installed, a full seal between the outlet nozzle 300 and the storage tank is not established. As such, a leakage path 392 is established by which contamination from outside air may enter the liquid chemical exiting the outlet nozzle 300.

As described with reference to FIG. 3A, the base portion 316 includes a lower surface 316a, which has an opening 316o of the second opening 352 defined therein. The O-ring 326 is adjacent the opening 314o. The locking structure 320 is adjacent the base portion 316 and is operable to press the lower surface 316a of the base portion 316 (including the opening 314o) against the O-ring 326. The locking structure 320 can have threads 322 that, in operation, interlock the locking structure 320 with the outlet 330 and tighten or loosen the locking structure 320 against the base portion 316.

In the leaking condition or “leak state,” the leakage path 392 is present. The leakage path 392 includes a gap between the O-ring 326 and the opening 314o. Namely, the leakage path 392 includes a gap between an upper surface 326a of the O-ring 326 and the opening 314o in the lower surface 316a of the base portion 316. As such, the O-ring 326 may not fully press against the lower surface 316a of the base portion 316 of the outlet nozzle 300.

In the leaking condition, when a gas 390 flows into the second opening 352 from the gas supply, the gas flows through the first leakage path 392. As such, a pressure meter (e.g., the pressure meter 180) in gas communication with the second opening 352 does not register a pressure of the gas that exceeds a selected pressure threshold value. In response to the pressure of the gas not exceeding the selected pressure threshold value, the controller (e.g., the controller 190) can determine that the outlet nozzle 300 is not properly installed, and can halt operation of the supply system (e.g., the system 100) that supplies liquid chemical in the storage drum to the semiconductor processing tools. Then, the outlet nozzle 300 can be reinstalled or reattached to achieve proper sealing thereof to the storage tank prior to entering a normal operating mode or state in which the liquid chemical is supplied to the semiconductor processing tools.

FIG. 3D illustrates a detailed diagrammatic view of a region of the outlet nozzle 300 during a sealed condition, in accordance with some embodiments.

In the sealed condition, the locking structure 320 is pressed against the base portion 316, which forms a full seal of the O-ring 326 against the opening 314o.

In the sealed condition, when the gas 390 flows into the second opening 352 from the gas supply, the gas is stopped by the seal formed by the contact of the O-ring 326 against the opening 314o. As such, the pressure meter (e.g., the pressure meter 180) in gas communication with the second opening 352 registers a pressure of the gas that exceeds the selected pressure threshold value. In response to the pressure of the gas exceeding the selected pressure threshold value, a controller (e.g., the controller 190) can determine that the outlet nozzle 300 is properly installed, and can engage normal operation of a supply system (e.g., the system 100) to supply the liquid chemical in the storage drum to the semiconductor processing tools.

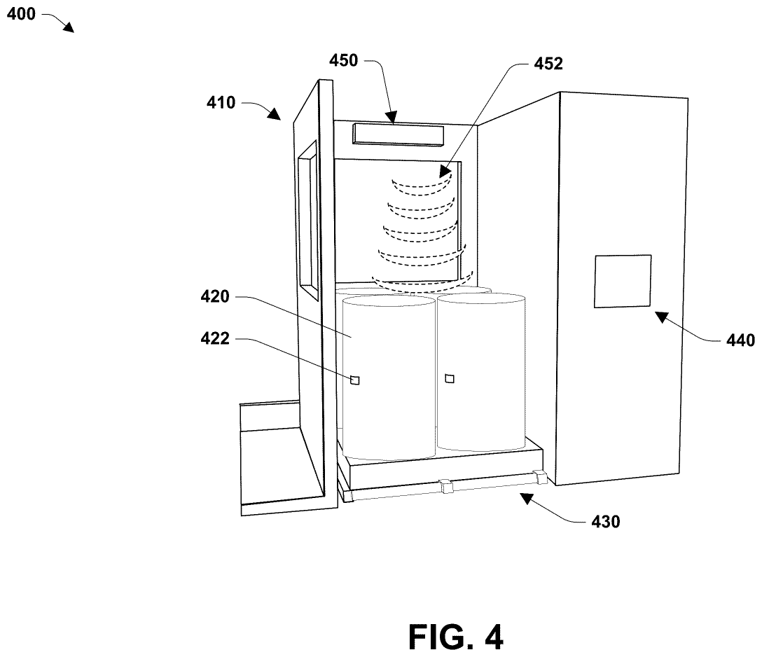

FIG. 4 illustrates a perspective view of an identification system 400 of a system (e.g., the system 100), in accordance with some embodiments.

In FIG. 4, the identification system 400 includes a housing 410. In some embodiments, a display apparatus 440 is mounted on or in the housing 410. The display apparatus 440 may be operable to display information associated with storage tanks 420 positioned in the housing 410.

The storage tanks 420 are similar in most respects or are embodiments of the storage tanks 120 described with reference to FIG. 1. Each of the storage tanks 420 can include an identifier tag 422 attached thereto. In some embodiments, the identifier tag 422 is a radio-frequency identification (RFID) tag. The identifier tag 422 can have encoded therein identification data, which can include one or more of (i) a serial number, (ii) manufacturer data, (iii) liquid chemical name data, (iv) manufacture date data, (v) batch data, (vi) lot data, (vii) expiration date data, (viii) other data and the like.

The identification system 400 includes a reading apparatus 450. In some embodiments, the reading apparatus 450 is an RFID reader. The reading apparatus 450 can be mounted on the housing 410. In operation, the reading apparatus 450 can retrieve the identification data stored in the identifier tag 422 on each of the storage tanks 420 via radio-frequency signals 452 directed toward the identifier tags 422. The identification data can be processed by the reading apparatus 450 or by an external processor, such as the controller 190 or another processor in data communication with the reading apparatus 450. In some embodiments, the reading apparatus 450 obtains the identification data from the identifier tag 422 and outputs the identification data to the controller 190 or other processor. The controller 190 or other processor can compare the identification data with identification data associated with the selected liquid chemical to determine whether the liquid chemical in the storage tank(s) 420 is the same as the selected liquid chemical. In response to the liquid chemical being different than the selected liquid chemical, the controller 190 or other processor can halt supply of the liquid chemical in the storage tank(s) 420 to a supply tank (e.g., the supply tank 130). Then, the storage tank(s) 420 containing the liquid chemical that is not the selected liquid chemical can be replaced with a storage tank(s) 420 that contains the selected liquid chemical. In response to the liquid chemical being the same as the selected liquid chemical, the controller 190 or other processor can continue with the normal operation mode or state in which the liquid chemical in the storage tank(s) 420 is supplied to the supply tank.

In some embodiments, instead of or in addition to the RFID reader, the reading apparatus 450 can include a vision-based system that uses one or more cameras and image recognition software to identify the storage tanks 420. For example, the storage tanks 420 can include markings that are identifiable by the reading apparatus 450, such that the reading apparatus 450 can determine based on the markings whether the storage tanks 420 contain the selected liquid chemical.

In some embodiments, the identification system 400 includes a platform 430 on which the storage tanks 420 are positioned. In some embodiments, the platform 430 can include a scale, which can obtain data associated with initial weight of full storage tanks 420 and ongoing data associated with in-use weight of the storage tanks 420 as the liquid chemical is removed therefrom to supply the semiconductor processing tools. In some embodiments, the initial weight can be included in identification of the liquid chemical in the storage tanks 420. For example, when the initial weight of the full storage tank 420 exceeds a stored initial weight of the full storage tank 420 associated with the liquid chemical, the platform 430 or a processor in data communication therewith can determine that the liquid chemical in the full storage tank 420 is not the selected liquid chemical.

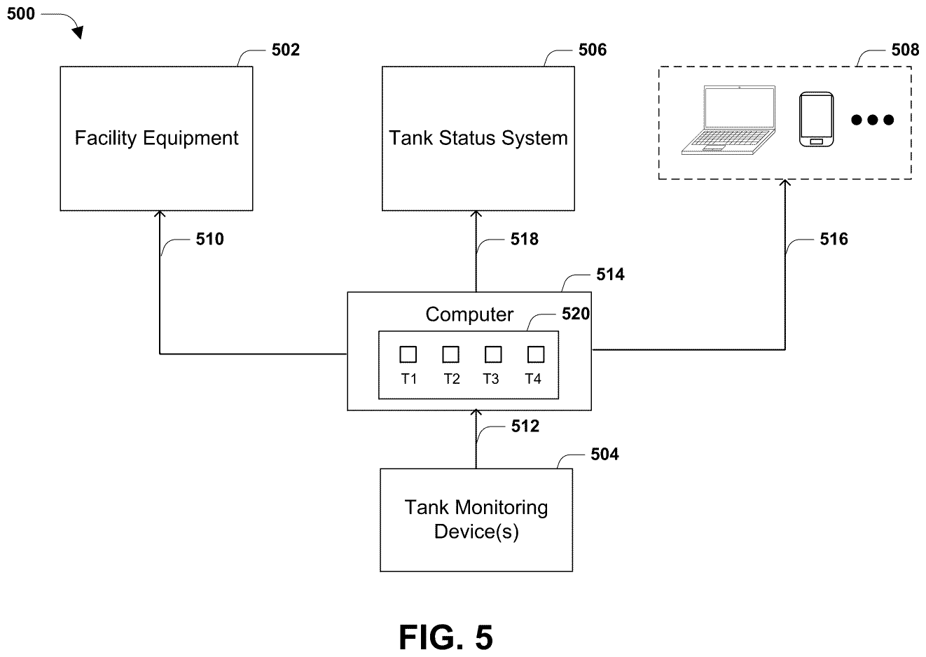

FIG. 5 illustrates a schematic view of a tank monitoring system 500, in accordance with some embodiments. The tank monitoring system 500 comprises at least one of a set of tank monitoring devices 504, facility equipment 502 of a facility, a computer 514, a status system 506, or one or more client devices 508. The set of tank monitoring devices 504 comprises sample monitoring devices distributed at various locations of the facility. The tank monitoring devices 504 are used to determine measurements associated with storage tanks and/or other equipment in the facility, such as the storage tanks 120 described with reference to FIG. 1.

In some embodiments, the set of tank monitoring devices 504 transmit a set of monitoring signals 512 to the computer 514. In some embodiments, each signal of the set of monitoring signals 512 is transmitted by a monitoring device (e.g., the pressure meter 180, the measurement apparatus 170 or the reading apparatus 450), of the set of tank monitoring devices 504, in a liquid chemical supply system of the facility. In some embodiments, one or more of the pressure meter 180, the measurement apparatus 170 and the reading apparatus 450 comprises a wireless communication module that transmits the respective signal to the computer 514 wirelessly. In some embodiments, one or more of the pressure meter 180, the measurement apparatus 170 and the reading apparatus 450 transmits the respective signal to the computer 514 over a wired connection between the pressure meter 180, the measurement apparatus 170 or the reading apparatus 450 and the computer 514.

In some embodiments, the set of monitoring signals 512 comprises a first tank monitoring signal from the pressure meter 180, the measurement apparatus 170 or the reading apparatus 450. In some embodiments, the first monitoring signal is indicative of the pressure of the gas flowed into the third opening 252 or the second opening 352 measured by the pressure meter 180.

In some embodiments, the set of monitoring signals 512 comprises a second monitoring signal from the pressure meter 180, the measurement apparatus 170 or the reading apparatus 450. In some embodiments, the second monitoring signal is indicative of one or more parameters (e.g., pH, specific gravity, etc.) associated with the liquid chemical 121 by the measurement apparatus 170.

In some embodiments, the set of monitoring signals 512 comprises a third monitoring signal from the pressure meter 180, the measurement apparatus 170, or the reading apparatus 450. In some embodiments, the third monitoring signal is indicative of identification data (e.g., manufacturer, liquid chemical name, etc.) associated with the liquid chemical 121 by the reading apparatus 450.

In some embodiments, the computer 514 controls a display panel 520 comprising a set of status indicators associated with apparatuses (e.g., the tanks 120, the tanks 420, etc.) of the liquid chemical supply system in the facility. In some embodiments, an indicator of the set of status indicators comprises a light, such as an indicator light, that indicates whether a corresponding apparatus is associated with a loose nozzle or wrong liquid chemical, wherein the light being in a first state indicates that the corresponding apparatus is associated with the loose nozzle or wrong liquid chemical and/or the light being in a second state indicates that the corresponding apparatus is not associated with the loose nozzle or wrong liquid chemical. In some embodiments, the display panel 520 comprises a display configured to display an alert indicative of one or more detected tank monitoring statuses of one or more apparatuses. In some embodiments, the first state corresponds to a first color emitted by the light, such as red or other color, and the second state corresponds to a second color emitted by the light, such as green or other color. The set of status indicators comprises at least one of a first indicator “T1” associated with a first apparatus (e.g., a first tank of the storage tanks 120, 420), a second indicator “T2” associated with a second apparatus (e.g., a second tank of the storage tanks 120, 420), a third indicator “T3” associated with a third apparatus (e.g., a third tank of the storage tanks 120, 420), a fourth indicator “T4” associated with a fourth apparatus (e.g., a fourth tank of the storage tanks 120, 420), or other indicator.

In some embodiments, the computer 514 provides one or more first signals 510 to the facility equipment 502. In some embodiments, the one or more first signals 510 are used to control at least some of the facility equipment 502, such as one, some or all liquid chemical supply systems of the facility and/or other equipment of the facility. In some embodiments, the one or more first signals 510 are generated using a signal generator of the computer 514. The one or more first signals 510 can be indicative of identity of liquid chemical in the liquid chemical supply system(s), whether an inlet or outlet nozzle is improperly installed, or both. In some embodiments, the computer 514 transmits the one or more first signals 510 to the facility equipment 502 wirelessly, such as using a wireless communication device of the computer 514. In some embodiments, the computer 514 transmits the one or more first signals 510 to the facility equipment 502 over a physical connection between the computer 514 and the facility equipment 502. In some embodiments, the computer 514 transmits the one or more first signals 510 to a controller (e.g., the controller 190) that controls one or more valves of the liquid chemical supply system.

In some embodiments, the computer 514 transmits a second signal 518 to the status system 506. The second signal 518 is generated using the signal generator of the computer 514. In some embodiments, the second signal 518 is indicative of at least one of (i) the set of tank monitoring statuses, (ii) the list of apparatuses that are determined to have a wrong liquid chemical or an improperly installed nozzle, or (iii) other information. In some embodiments, the computer 514 transmits the second signal 518 to the status system 506 wirelessly, such as using the wireless communication device of the computer 514. In some embodiments, the computer 514 transmits the second signal 518 to the status system 506 over a physical connection between the computer 514 and the status system 506. In some embodiments, the status system 506 triggers an alarm function based upon the second signal 518. In some embodiments, the status system 506 triggers the alarm function based upon the second signal 518 indicating that the apparatus is associated with a wrong liquid chemical, a loose nozzle, or both. In some embodiments, in response to triggering the alarm function, an alarm message is displayed via a display of the status system 506. The alarm message comprises at least one of an indication that the apparatus is associated with the wrong liquid chemical or loose nozzle, an indication of lead time to perform preventative maintenance, an indication comprising an instruction for the liquid chemical supply system to cease operating (until the nozzle is properly installed, for example), or other indication. In some embodiments, an alarm sound is output via a speaker connected to the status system 506 in response to triggering the alarm function.

In some embodiments, the computer 514 transmits a third signal 516 to one or more client devices 508. The one or more client devices 508 comprise at least one of a phone, a smartphone, a mobile phone, a landline, a laptop, a desktop computer, hardware, or other type of client device. The third signal 516 is generated using the signal generator of the computer 514. In some embodiments, the third signal 516 is indicative of at least one of (i) the set of tank monitoring statuses, (ii) the list of apparatuses that are determined to have a wrong liquid chemical or an improperly installed nozzle, or (iii) other information. In some embodiments, the computer 514 transmits the third signal 516 to a client device of the one or more client devices 508 wirelessly, such as using the wireless communication device of the computer 514. In some embodiments, the computer 514 transmits the third signal 516 to a client device of the one or more client devices 508 over a physical connection between the computer 514 and the client device. In some embodiments, the third signal 516 comprises a message, such as at least one of an email, a text message, etc., transmitted in response to detecting the wrong liquid chemical and/or the loose nozzle(s). In some embodiments, in response to detecting a wrong liquid chemical and/or a loose nozzle(s) associated with an apparatus, a telephonic call is made to a client device, such as a landline or a mobile phone, of the one or more client devices 508, such as using a dialer of the computer 514.

In some embodiments, the set of monitoring signals 512 are used as feedback based upon which operation of the facility equipment 502 is controlled by the computer 514. In some embodiments, the computer 514 controls operation of the facility equipment 502 based upon measurements provided by the set of monitoring signals 512. In some embodiments, operation of the facility equipment 502 is controlled using the one or more first signals 510. In some embodiments, a signal of the one or more first signals 510 is indicative of one or more instructions.

In some embodiments, the system 100 of the facility equipment 502 at least one of ceases operation, enters a locked state, or performs another operation in response to receiving a signal (of the one or more first signals 510) indicating that the wrong liquid chemical is installed or the inlet or outlet nozzle is improperly fitted to the storage tank. In some embodiments, the one or more first signals 510 comprise a signal transmitted to a machine, such as the system 100. In some embodiments, the signal instructs the machine to engage one storage tank 120 while another storage tank 120 is undergoing preventative maintenance. In some embodiments, the signal allocates one or more resources (e.g., manpower, a robot, one or more tools, the replacement component, etc.) to the another storage tank 120 to be used for remedying the halt associated with the another storage tank 120. In some embodiments, determination of whether the inlet or outlet nozzle is improperly fitted to the storage tank is performed continuously during supply of the liquid chemical.

In some embodiments, in response to determining that the another storage tank 120 is not associated with a halt, the another storage tank 120 is used to supply liquid chemical 121 to the tool(s) 150, so as to perform an etching process or other suitable process on the semiconductor wafer. In some embodiments, in response to determining that the another storage tank 120 is associated with the halt, the computer 514 instructs the another storage tank 134 to not deliver the liquid chemical 121 (until the halt is addressed, for example). During the system 100 not delivering the liquid chemical 121 via the another storage tank 120, the system 100 may deliver the liquid chemical 121 via another storage tank, such as the one storage tank 120.

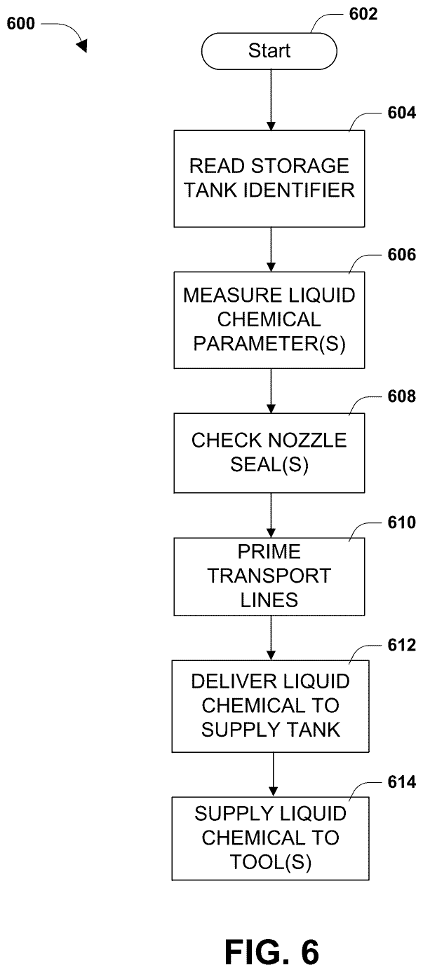

FIG. 6 is a flow diagram illustrating a method 600 of operating a liquid chemical supply system, in accordance with some embodiments.

The method 600 is illustrated in FIG. 6 in accordance with some embodiments. In some embodiments, the method 600 is performed by the system 100. In some embodiments, the method 600 is performed by a system different than the system 100.

The method begins at 602.

At 604, the method 600 includes reading a storage tank identifier. In some embodiments, 604 is performed by the reading apparatus described with reference to FIG. 4. In response to the identification data read by the reading apparatus being different than identification data associated with a selected liquid chemical, a warning notification may be issued, the system 100 may be halted, or another suitable action may be taken. Some suitable actions are described with reference to FIG. 5.

At 606, the method 600 includes measuring one or more parameters of the liquid chemical contained in the storage tank. In some embodiments, 606 is performed by the measurement apparatus 170 as described with reference to FIG. 1 and FIG. 5. In response to the one or more parameters of the liquid chemical being different than parameters associated with the selected liquid chemical, a warning notification may be issued, the system 100 may be halted, or another suitable action may be taken. Some suitable actions are described with reference to FIG. 5.

At 608, the method 600 includes checking seal(s) of the inlet nozzle and/or the outlet nozzle. In some embodiments, 608 may be performed by the pressure meter 180 and optionally the controller 190 in data communication with the pressure meter 180, as described with reference to FIG. 1. In response to the pressure of the gas input to the inlet and/or outlet nozzle not exceeding the selected pressure threshold value, a warning notification may be issued, the system 100 may be halted, or another suitable action may be taken. Some suitable actions are described with reference to FIG. 5.

At 610, the method 600 includes priming transport lines. In some embodiments, 610 may be performed by the pump 140, the filtration system or filter 144 the transport lines 146, 148 and the inlet nozzle(s) 126. Although not shown in FIG. 1 for simplicity of illustration, a valve may be present between the transport line 148 and the supply tank 130. In one example of 610, the pump 140 may pump the liquid chemical 121 while the valve controlling flow to the supply tank 130 is closed. The pumping can be for a selected period of time, such as between about 1 minute and about 10 minutes. The pumping removes air (e.g., bubbles) from the transport line 146 and filters the liquid chemical 121 in preparation for pumping the liquid chemical 121 to the supply tank 130.

At 612, the method 600 includes delivering the liquid chemical to the supply tank. In some embodiments, 612 is performed by the pump 140. Following priming the transport lines in 610, the valve controlling flow to the supply tank 130 may be opened and the pump 140 may pump the liquid chemical 121 to the supply tank.

At 614, the method 600 includes supplying the liquid chemical to one or more tools. In some embodiments, 614 is performed by the pump 142, which pumps the liquid chemical from the supply tank 130 to the tools 150.

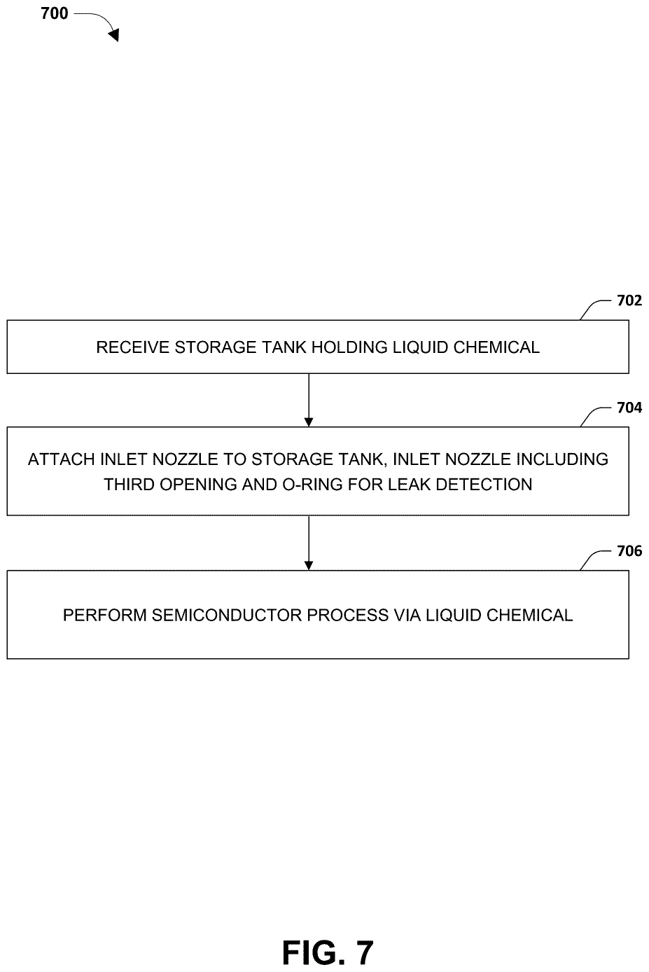

FIG. 7 is a flow diagram illustrating a method 700, in accordance with some embodiments.

The method 700 is illustrated in FIG. 7 in accordance with some embodiments. At 702, the method 700 includes receiving a storage tank holding a liquid chemical. At 704 the method 700 includes attaching an inlet nozzle to the storage tank, the inlet nozzle including a third opening and an O-ring for leak detection. At 706, the method 700 includes performing a semiconductor process via the liquid chemical.

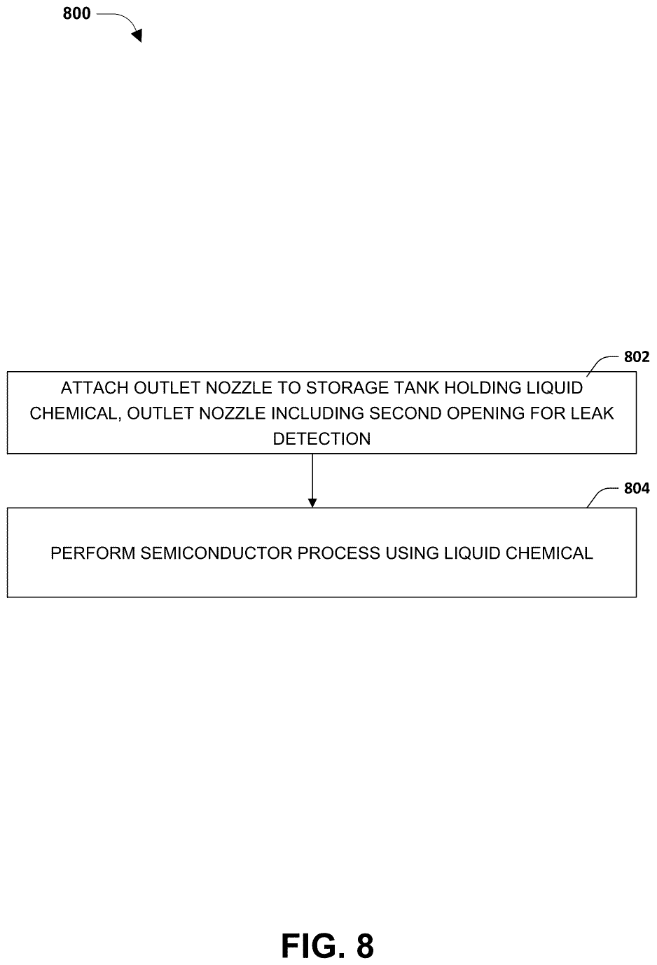

FIG. 8 is a flow diagram illustrating a method 800, in accordance with some embodiments.

A method 800 is illustrated in FIG. 8 in accordance with some embodiments. At 802, the method 800 includes attaching an outlet nozzle to a storage tank holding a liquid chemical, the outlet nozzle including a second opening for leak detection. At 804, the method 800 includes performing a semiconductor process using the liquid chemical.

FIG. 9 illustrates an example computer-readable medium wherein processor-executable instructions configured to embody one or more of the provisions set forth herein may be comprised, according to some embodiments.

One or more embodiments involve a computer-readable medium comprising processor-executable instructions configured to implement one or more of the techniques presented herein. An exemplary computer-readable medium is illustrated in FIG. 9, wherein the embodiment 900 comprises a computer-readable medium 908 (e.g., a CD-R, DVD-R, flash drive, a platter of a hard disk drive, etc.), on which is encoded computer-readable data 906. This computer-readable data 906 in turn comprises a set of processor-executable computer instructions 904 configured to implement one or more of the principles set forth herein when executed by a processor. In some embodiments 900, the processor-executable computer instructions 904 are configured to implement a method 902, such as at least some of the aforementioned method(s) when executed by a processor. In some embodiments, the processor-executable computer instructions 904 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: receiving a storage tank that holds a liquid chemical therein; attaching an inlet nozzle to the storage tank, the inlet nozzle including: a first opening defined therein, the first opening in fluid communication with an interior of the storage tank; a second opening defined therein, the second opening in gas communication with the interior of the storage tank; a third opening defined therein; and a first O-ring in contact with the third opening; and performing a semiconductor process via the liquid chemical.

In some embodiments, a method is provided. The method includes: attaching an outlet nozzle to a storage tank holding a liquid chemical, the outlet nozzle including: a body, a lower surface of the body being in contact with an O-ring of a tube that extends into an interior of the storage tank; a first opening defined in the body, the first opening in fluid communication with an interior of the storage tank via the tube; and a second opening defined in the body, the second opening having an outlet hole defined in the lower surface of the body; and performing a semiconductor process via the liquid chemical.

In some embodiments, a system is provided. The system includes: a storage tank operable to hold a liquid chemical; an inlet nozzle operable to attach to the storage tank at an inlet opening defined in the storage tank, the inlet nozzle including: a body; a first opening defined in the body and in fluid communication with the storage tank; a second opening defined in the body and in gas communication with the storage tank via a gas inlet of the storage tank; a third opening defined in the body; and a first O-ring in contact with the third opening; and a semiconductor processing tool in fluid communication with the storage tank.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
receiving a storage tank that holds a liquid chemical therein;
attaching an inlet nozzle to the storage tank, the inlet nozzle including:
a first opening defined therein, the first opening in fluid communication with an interior of the storage tank;
a second opening defined therein, the second opening in gas communication with the interior of the storage tank;
a third opening defined therein; and
a first O-ring in contact with the third opening; and
performing a semiconductor process via the liquid chemical.

2. The method of claim 1, comprising:
following attaching the inlet nozzle, outputting the liquid chemical from the storage tank by flowing a first gas through the second opening.

3. The method of claim 2, comprising prior to outputting the liquid chemical:
determining whether a seal is present between the inlet nozzle and the storage tank by flowing a second gas through the third opening.

4. The method of claim 3, wherein determining whether the seal is present includes determining whether the seal is present between the inlet nozzle, a second O-ring and the storage tank.

5. The method of claim 2, comprising following outputting liquid chemical:
filtering the liquid chemical via a filter assembly; and
following filtering the liquid chemical, outputting the liquid chemical from the filter assembly to the storage tank via the first opening.

6. The method of claim 1, wherein receiving the storage tank includes determining whether the liquid chemical is a selected liquid chemical by reading a radio frequency identifier tag of the storage tank.

7. The method of claim 6, comprising:
determining whether the liquid chemical is the selected liquid chemical by pumping the liquid chemical into a measurement apparatus in fluid communication with the storage tank.

8. A method, comprising:
attaching an outlet nozzle to a storage tank holding a liquid chemical, the outlet nozzle including:
a body, a lower surface of the body being in contact with an O-ring of a tube that extends into an interior of the storage tank;
a first opening defined in the body, the first opening in fluid communication with an interior of the storage tank via the tube; and
a second opening defined in the body, the second opening having an outlet hole defined in the lower surface of the body; and
performing a semiconductor process via the liquid chemical.

9. The method of claim 8, comprising:
outputting the liquid chemical from the storage tank via the first opening.

10. The method of claim 8, comprising prior to outputting the liquid chemical:
determining whether a seal is present between the outlet nozzle and the tube by flowing a gas through the second opening.

11. The method of claim 10, wherein determining whether the seal is present includes measuring pressure of the gas during flowing the gas through the second opening.

12. The method of claim 8, comprising:
pumping the liquid chemical from the storage tank to a buffer tank; and
pumping the liquid chemical from the buffer tank to a semiconductor processing tool that performs the semiconductor process.

13. The method of claim 12, comprising during pumping the liquid chemical from the storage tank to the buffer tank:
stabilizing pressure of the storage tank via an opening defined in an inlet nozzle attached to the storage tank.

14. The method of claim 13, comprising prior to outputting the liquid chemical:
determining whether a seal is present between the inlet nozzle and the storage tank by flowing a gas through a third opening defined in the inlet nozzle.

15. The method of claim 14, wherein flowing the gas through the third opening includes:
flowing the gas into a space between a first O-ring in contact with the third opening and a second O-ring in contact with the storage tank and the inlet nozzle.

16. A system, comprising:
a storage tank operable to hold a liquid chemical;
an inlet nozzle operable to attach to the storage tank at an inlet opening defined in the storage tank, the inlet nozzle including:
a body;
a first opening defined in the body and in fluid communication with the storage tank;
a second opening defined in the body and in gas communication with the storage tank via a gas inlet of the storage tank;
a third opening defined in the body; and
a first O-ring in contact with the third opening; and
a semiconductor processing tool in fluid communication with the storage tank.

17. The system of claim 16, comprising:
a gas supply in gas communication with the second opening and the third opening; and
a pressure meter in gas communication with the gas supply and the third opening.

18. The system of claim 17, wherein the system, in operation:
supplies a gas from the gas supply to the third opening;
flows the gas into a space between the first O-ring and a second O-ring, the second O-ring being in contact with the storage tank and the body of the inlet nozzle; and
determines whether a leak is present between the inlet nozzle and the storage tank at the second O-ring by measuring pressure of the gas by the pressure meter.

19. The system of claim 16, comprising:
a tube that extends into the storage tank via an outlet opening defined in the storage tank; and
an outlet nozzle operable to attach to the storage tank at the outlet opening, the outlet nozzle including:
an outlet nozzle body having a lower surface in contact with an upper surface of the tube;
a fourth opening defined in the outlet nozzle body and in fluid communication with the storage tank; and
a fifth opening defined in the outlet nozzle body, the fifth opening having an outlet hole defined in the lower surface of the outlet nozzle body.

20. The system of claim 19, wherein the system, in operation:
supplies a gas from a gas supply to the fifth opening; and
determines whether a leak is present between the outlet nozzle and the tube by measuring pressure of the gas by a pressure meter.
